(19) United States
(12) Patent Application Publication
(10) Pub. No.: US 2022/0019716 A1
(43) Pub. Date: Jan. 20, 2022

(54) Systems and Methods for Enhanced Engineering Design and Optimization

(71) Applicants: Yashar Kiarashinejad, Atlanta, GA (US); Sajjad Abdollahramezani, Atlanta, GA (US); Ali Adibi, Atlanta, GA (US)

(72) Inventors: Yashar Kiarashinejad, Atlanta, GA (US); Sajjad Abdollahramezani, Atlanta, GA (US); Ali Adibi, Atlanta, GA (US)

(21) Appl. No.: 17/294,837

(22) PCT Filed: Nov. 20, 2019
(86) PCT No.: PCT/US2019/062489

§ 371 Date: May 18, 2021

Related U.S. Application Data
(60) Provisional application No. 62/770,119, filed on Nov. 20, 2018.

(51) Int. Cl. G06F 30/27; G06N 3/04; G06N 3/08

(52) U.S. Cl. CPC G06F 30/27; G06N 3/088; G06N 3/084; G06N 3/0454

(57) ABSTRACT

Disclosed are systems and method for enhanced engineering design and optimization incorporating double-step dimensionality-reduction in order to provide customized, automated solutions to the design and optimization of electromagnetic nanostructures. The system can train a multi-stage neural network reduce the response space of a design problem. The system can train a second neural network to reduce the design space of the design problem. As a result of these reductions, the system can generate a one-to-one relationship between the design and response spaces of complex design problems. The system can subsequently solve both the forward design and the inverse problem. Additionally, the system can utilize the generated neural networks to determine a plurality of analytical relationships between the design space and the response space. The system can then utilize the determined relationship to arrive at optimal design solutions.

### CROSS-REFERENCE TO RELATED APPLICATIONS

This Application claims priority, and benefit under 35 U.S.C. § 119(e), to U.S. Provisional Patent Application No. 62/770,119, filed 20 Nov. 2018, the entire contents of which is hereby incorporated by reference as if fully set forth below.

### STATEMENT OF RIGHTS UNDER FEDERALLY SPONSORED RESEARCH

This invention was made with government support under Award No. N00014-18-1-2055 awarded by the Office of Naval Research. The government has certain rights in the invention.

### FIELD OF INVENTION

Examples of the present disclosure relate to systems and methods for enhanced engineering design and optimization, and more particularly to systems and methods for enhanced engineering design and optimization incorporating double-step dimensionality-reduction to provide customized, automated solutions to the design and optimization of electromagnetic nanostructures.

### BACKGROUND

Designers of electronic devices and components frequently employ design tools to aid them. Such computer-aided design (CAD) makes use of automated rule checking and stock component types to allow a designer to rapidly create full circuit designs that conform to the requirements of the fabrication technology to be used.

While electronic design is well established, nanophotonic integrated circuits are a fast-emerging domain and present design technologies are inadequate. Traditional design and optimization approaches for such nanophotonic structures rely on using analytical or semi-analytical modeling or even brute-force analysis. Such approaches are limited to structures having relatively simple designs as the computational requirements to completely study and model such structures are high.

Further, as researchers are able to form increasingly more complex nanostructures with multiple design parameters, these traditional design methods become less and less feasible. For example, as the number of design parameters increases so does the computational requirements for generating and analyzing such designs.

Additionally, as such nanostructures become more and more complex, it becomes ever more important to understand all possible design options as well as the role that different design parameters play in the functionality of such nanostructures.

Some emerging solutions have suggested combatting these problems by utilizing neural networks, however such solutions have been limited to the simple nanostructures due to the reduced computational complexity afforded due to the one-to-one relationship between design parameters and output response. However, such approaches fail to account for the fact that most of the most promising nanostructures do not exhibit such a one-to-one relationship, thus such solutions ultimately provide little to no improvement over the brute force techniques.

Accordingly, there is a need for systems and methods for enhanced engineering design and optimization capable of providing efficient and unique solutions for design problems exhibiting a many-to-one relationship between design parameters and output characteristics. Specifically, there is a need for systems and methods for enhanced engineering design and optimization of complex electromagnetic nanostructures. Examples of the present disclosure are directed to these and other considerations.

### SUMMARY

Examples of the present disclosure comprise systems and methods for enhanced engineering design and optimization, and more particularly to systems and methods for enhanced engineering design and optimization incorporating double-step dimensionality-reduction to provide customized, automated solutions to the design and optimization of electromagnetic nanostructures.

Further features of the disclosed design, and the advantages offered thereby, are explained in greater detail hereinafter with reference to specific examples illustrated in the accompanying drawings, wherein like elements are indicated be like reference designators.

### BRIEF DESCRIPTION OF THE DRAWINGS

Reference will now be made to the accompanying drawings, which are not necessarily drawn to scale, are incorporated into, and constitute a portion of, this disclosure, illustrate various implementations and aspects of the disclosed technology and, together with the description, serve to explain the principles of the disclosed technology. In the drawings:

FIG. 1 is a diagram of an example system that may be used to implement one or more examples of the present disclosure;

FIG. 2 is a graphic depicting a method for enhanced engineering design and optimization incorporating double-step dimensionality-reduction, in accordance with some examples of the present disclosure;

FIGS. 3A and 3B are flowcharts of a method for enhanced engineering design and optimization incorporating double-step dimensionality-reduction, in accordance with some examples of the present disclosure;

FIG. 4 is a flowchart of a method for enhanced engineering design and optimization incorporating double-step dimensionality-reduction to provide customized, automated solutions to the design and optimization of electromagnetic nanostructures, in accordance with some examples of the present disclosure;

FIG. 5 is a component diagram of an example of a user device, in accordance with some examples of the present disclosure;

FIG. 6 is a component diagram of an example of a server, in accordance with some examples of the present disclosure;

FIG. 7 is a component diagram of an example electromagnetic nanostructure utilized in an example implementation of the present disclosure; and

FIG. 8 is a graph depicting the performance of potential designs of the electromagnetic structure of FIG. 7 developed using systems and methods of the present disclosure.

### DETAILED DESCRIPTION

Examples of the present disclosure relate to systems and methods for enhanced engineering design and optimization capable of providing efficient and unique solutions for design problems exhibiting a many-to-one relationship between design parameters and output characteristics. Throughout, much of the discussion herein is directed towards systems and methods for enhanced engineering design and optimization of complex electromagnetic nanostructures.

The system for enhanced engineering design and optimization can incorporate double-step dimensionality-reduction in order to provide customized, automated solutions to the design and optimization of such problems electromagnetic nanostructures. The system can train a multi-stage neural network reduce the response space of a design problem. The system can train a second neural network to reduce the design space of the design problem. As a result of these reductions, the system can generate a one-to-one relationship between the design and response spaces of complex design problems. The system can subsequently solve both the forward design (e.g., given the design parameters, determine the response) and the inverse problem (e.g., given a desired response, determine the necessary design parameters). Additionally, the system can utilize the generated neural networks to determine a plurality of analytical relationships between the design space and the response space. The system can then utilize the determined relationship to arrive at optimal design solutions.

Some implementations of the disclosed technology will be described more fully with reference to the accompanying drawings. This disclosed technology, however, may be embodied in many different forms and should not be construed as limited to the implementations set forth herein. The components described hereinafter as making up various elements of the disclosed technology are intended to be illustrative and not restrictive. Many suitable components that could perform the same or similar functions as components described herein are intended to be embraced within the scope of the disclosed systems and methods. Such other components not described herein may include, but are not limited to, for example, components developed after development of the disclosed technology.

It is also to be understood that the mention of one or more method steps does not imply a particular order of operation or preclude the presence of additional method steps or intervening method steps between those steps expressly identified. Similarly, it is also to be understood that the mention of one or more components in a device or system does not preclude the presence of additional components or intervening components between those components expressly identified.

Reference will now be made in detail to example examples of the disclosed technology, examples of which are illustrated in the accompanying drawings and disclosed herein. Wherever convenient, the same references numbers will be used throughout the drawings to refer to the same or like parts.

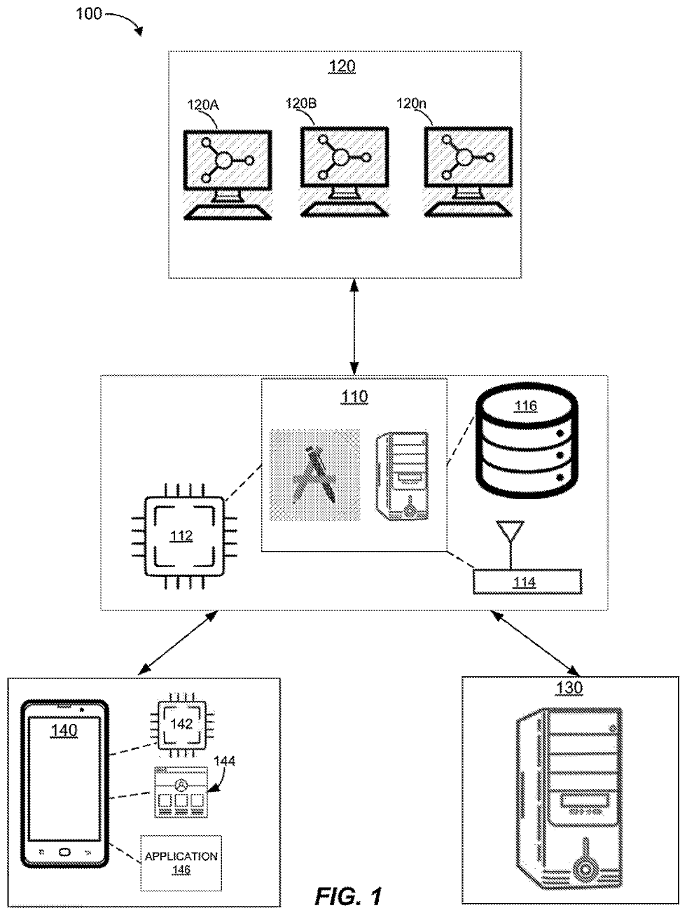

FIG. 1 shows an example system 100 that may implement certain methods for engineering design and optimization as disclosed herein. As shown in FIG. 1, in some implementations the system 100 can include one or more simulation devices 120A-120n, a server 130, a user device 140, and a design and optimization server 110, which may include one or more processors 112, a transceiver 114, and a database 116, among other things. The user device 140 can include one or more processors 142, a graphical user interface (GUI) 144, and an application 146.

The simulation devices 120A-120n can represent computer simulation devices and/or one or more neural networks that have been pre-trained based on simulation data. The server 130 may belong to a third-party aggregator, for example, that stores data, such as neural network training data, simulation data, or other data necessary to implement the methods described herein.

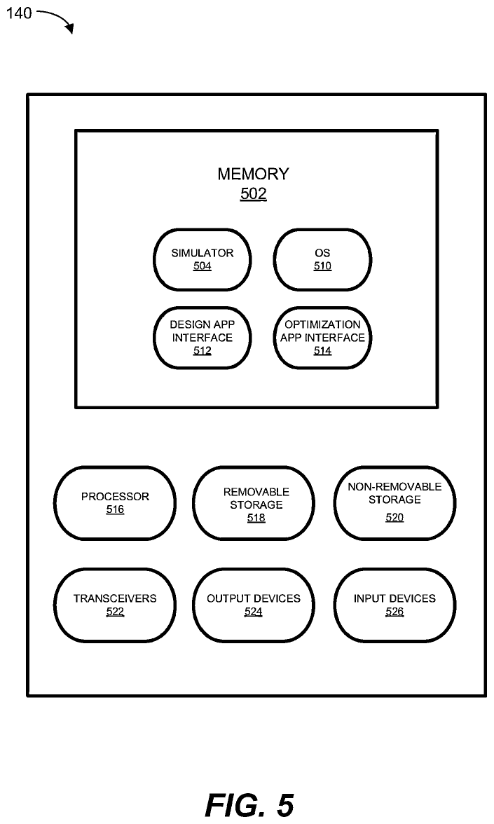

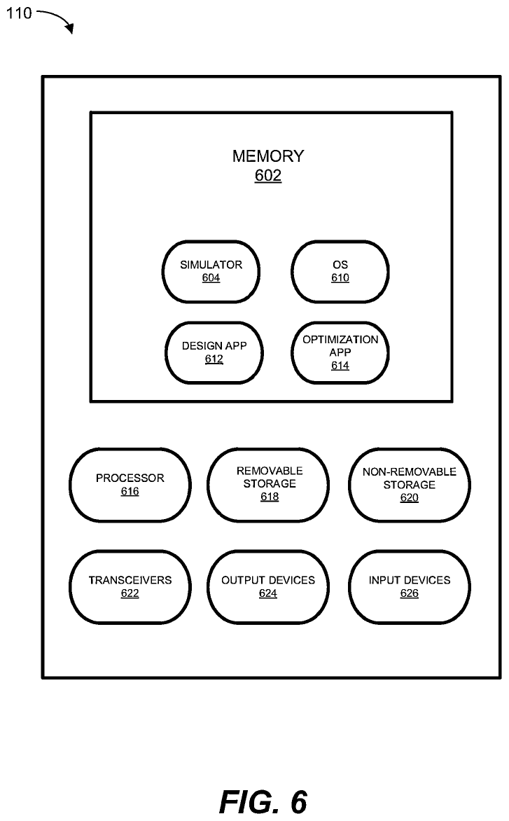

The user device 140 can be, for example, a personal computer, a smartphone, a laptop computer, a tablet, a wearable device (e.g., smart watch, smart jewelry, head-mounted displays, etc.), or other computing device. An example computer architecture that can be used to implement the user device 140 is described below with reference to FIG. 5. The design and optimization server 110 can include one or more physical or logical devices (e.g., servers) or drives and may be implemented as a single server, a bank of servers (e.g., in a “cloud”), run on a local machine, or run on a remote server. An example computer architecture that can be used to implement the design and optimization server 110 is described below with reference to FIG. 6.

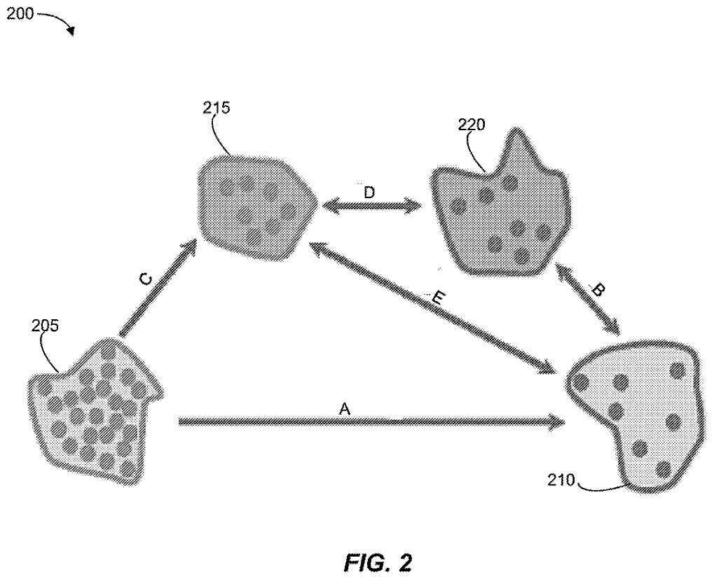

FIG. 2 depicts a graphical display of method 200 for enhanced engineering design and optimization incorporating double-step dimensionality-reduction. As depicted, method 200 can begin with a design space 205 (e.g., all of the possible designs) and a related response space 210 (e.g., all of the possible responses). The design space 205 and response space 210 can be generated using simulation software. For example, when designing electromagnetic nanostructures, electromagnetic simulation software can be utilized to generate the design space 205 and the response space 210. Path A depicts the relationships between design space 205 and response space 210. As shown, path A indicates that the relationship between the design space 205 and the response space 210 to be a many-to-one relationship, indicating that multiple sets of design parameters may result in a given response. As will be appreciated, such a relationship leads to a nonuniqueness problem, meaning that there may be more than one solution for a given desired response. As will be further appreciated, many-to-one problems also involve a great deal of computational complexity in order to arrive at one of the many nonunique solutions. It is such problems that method 200 seeks to solve.

As further depicted in FIG. 2, the method 200 involves the generation of a reduced response space 220. The method 200 can utilize a neural network to perform dimensionality reduction of the response space 210 in order to generate the reduced response space 220. For example, the method 200 could utilize an autoencoder in order to perform the dimensionality reduction. Path B depicts the relationships between response space 210 and reduced response space 220. As shown, path B indicates that the relationship between the response space 210 and reduced response space 220 to be a one-to-one relationship, indicating each feature in the reduced response space 220 is related to the features of the response space 210 through a defined function.

Next, method 200 involves the generation of a reduced design space 215. The method 200 can utilize a trained neural network to relate the design space 205 to the reduced response space 220. For example, the method 200 could train a neural network with input data from the design space 205 and output data from the reduced response space 220, in order to generate the reduced design space 215. Path C depicts the relationship between the design space 205 and the reduced design space 215. As shown, path C indicates that the relationship between the design space 205 and the response space 210 to be a many-to-one relationship, indicating that multiple sets of design parameters may result in a given response. As previously mentioned, this many-to-one relationship creates a nonuniqueness problem, however, as will be appreciated, because the method 200 generates the many-to-one relationship through a trained neural network, the many-to-one/one-to-many relationships are available via analyzing the training process. For example, by analyzing the various layers of the neural network. Accordingly, the method 200 can convert back and forth between the design space 205 and the reduced design space 215. Further, method 200 can involve accounting for and imposing physical device constraints, such as, for example, fabrication limitations, on the iterative layer by layer process in order to reduce the number of possible solutions.

Path D depicts the relationships between reduced design space 215 and reduced response space 220. As shown, path D indicates that the relationship between the reduced design space 215 and reduced response space 220 to be a one-to-one relationship, indicating each feature in the reduced response space 220 is related to the features of the reduced design space 215 through a defined function. Further, path E depicts the relationships between reduced design space 215 and response space 210. As shown, path E indicates that the relationship between the reduced design space 215 and response space 210 to be a one-to-one relationship, indicating each feature in the response space 210 is related to the features of the reduced design space 215 through a defined function. As will be appreciated, by reducing the dimensionality of the relevant spaces, the method 200 drastically reduces the computational complexity, which substantially decreases the computation costs associated with design and optimization problems.

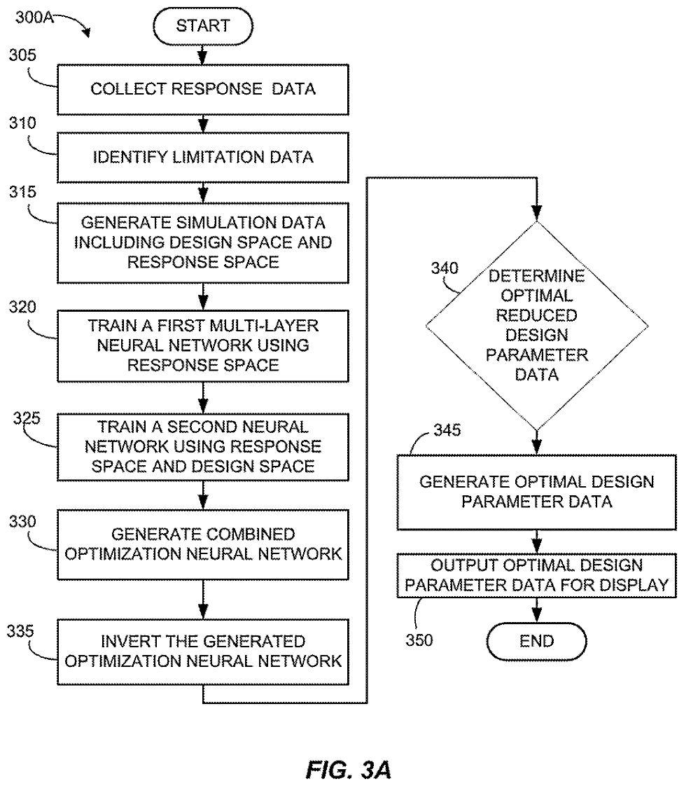

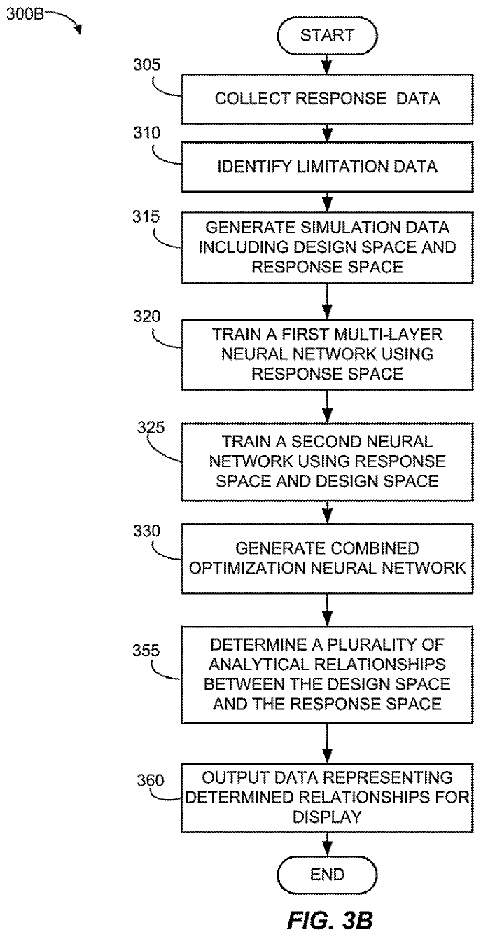

FIG. 3A is a flowchart of an example of a method 300A for enhanced engineering design and optimization from the perspective of the design and optimization server 110. The method 300A can be performed by the design and optimization server 110, the user device 140, the server 130, the simulation devices 120A-120n, or any combination thereof.

The design and optimization server 110 may be in communication with the user device 140, the simulation devices 120A-120n, and the server 130. Further, the design and optimization server 110 can receive response and simulation data from the server 130 and/or the simulation devices 120A-120n, train first and second neural networks to reduce the design and response spaces respectively, generate and invert a combined neural network, determine optimal design parameter data, and output the determined parameters to the user device 140 for display.

At 305, the design and optimization server 110 can collect response data, which can be stored in the database 116. The response data can be response data received from a user (e.g., user device 140) and/or or response data received from the server 130. As previously mentioned, response data can include data associated with a desired response based on a set of known input parameters. For example, response data can include scattering efficiency from a cluster of nanoparticles under illumination of laser monochromatic light, absorption spectra of an array of synthesized metallo-dielectric nanospheres due to the excitation with a broadband light source, desired wavefront conversion data associated with a given photonic nanostructure, optimal fuel efficiency for a hybrid electric vehicle transmission design, in addition to many desired responses of complex, many-to-one, design and optimization problems (e.g., spiking rate of motor and visual cortex neurons under excitation of external stimuli, effect of various pathogens on the malfunctioning of malignant cells, air pollution gauging exposed to contaminating agents, global warming investigation due to emitted greenhouse gasses, and others as will be understood by one of skill in the art). The design and optimization server 110 can generate a graphical user interface (“GUI”) comprising a fillable form. The design and optimization server 110 can then transmit the GUI to the user device 140 for presentation to a user. The user device 140 can collect the desired response data via the fillable form of the GUI and transmit the desired response data to design and optimization server 110.

At 310, the design and optimization server 110 can identify, based on the desired response data, limitation data, which can be stored in the database 116. Limitation data can include data associated with the structure of a physical product to be designed. For example, limitation data may include material properties, potential nanostructure geometry, periodic/non-periodic, unit-cell structure, and fabrication limitations. The limitation data can be limitation data received from a user (e.g., user device 140) and/or or limitation data received from the server 130. The limitation data can comprise limitation data comprises structural limitation data relating to physical properties of a photonic nanostructure, such as, for example, a metasurface. Further, the design and optimization server 110 can train a neural network to determine limitation data based on desired response data.

At 315, the design and optimization server 110 can generate, based on the limitation data, simulation data comprising a design space and a response space, which can be stored in the database 116. Simulation data can include randomly generated parameters. For example, simulation data can include a design space comprising a plurality of randomly generated design parameters and a response space comprising calculated response data associated with the plurality of randomly generated design parameters. The simulation data can be simulation data received from a user (e.g., user device 140) and/or or simulation data received from the server 130. The simulation data can include training data, including a portion of the design and response spaces, and verification data, including the remainder of the design and response spaces.

At 320, the design and optimization server 110 can train, using the response space, a first multi-layer neural network to generate a reduced response space having reduced dimensionality compared to the response space, the first multi-layer neural network comprising an encoding layer, one or more hidden layers, and a decoding layer. The first multi-layer neural network can be an autoencoder that dimensionally reduces the response space to generate the reduced response space. The one or more hidden layers can range from 3 to 9. The one or more hidden layers can be 4. The autoencoder can utilize mean squared error as the cost function. The autoencoder can minimize error using the backpropagation method. The activation function for the neural network can comprise a tangent sigmoid. The activation function for the neural network can comprise one of rectified linear unit (Relu) and tangent hyperbolic. The training optimizer for the neural network can comprise one of adaptive moment estimation, stochastic gradient descent, mini-batch gradient descent, and other suitable optimizers. The learning rate for the neural network can be between 10⁻⁶ and 10⁻⁵.

At 325, the design and optimization server 110 can train, using the design space and the response space, a second neural network to generate a reduced design space having reduced dimensionality compared to the design space. The neural network can utilize mean squared error as the cost function. The neural network can minimize error using the backpropagation method. The activation function for the neural network can comprise a tangent sigmoid. The activation function for the neural network can comprise one of rectified linear unit (Relu) and tangent hyperbolic. The training optimizer for the neural network can comprise one of adaptive moment estimation, stochastic gradient descent, mini-batch gradient descent, and other suitable optimizers. The learning rate for the neural network can be between 10⁻⁶ and 10⁻⁵.

At 330, the design and optimization server 110 can generate, by cascading the second neural network with the decoding layer of the first multi-layer neural network, an optimization neural network. For example, in some implementations, the output of the first neural network can be fed into the second neural network, which turns the conventional many-to-one problem into two more manageable sub-problems, each of which can be modeled using a respective neural network (i.e., the first and second neural networks). As will be appreciated, this approach provides greater accuracy since the first neural network squeezes the space to make the input-output relation closer to one-to-one. The optimization neural network can comprise a plurality of neural networks.

At 335, the design and optimization server 110 can invert, using the design space and a response space, the optimization neural network to generate a design generation neural network. For example, in some implementations, an untrained neural network can be connected with the optimization network. The resultant neural network can then be trained using the design and response space and then detach the optimization network, resulting in the previously un trained network becoming and inverted version of the optimization network.

At 340, the design and optimization server 110 can determine, based on applying the design generation neural network to the desired response data, optimal reduced design parameter data, wherein the reduced design space comprises the optimal reduced design parameter data.

At 345, the design and optimization server 110 can generate, by applying the encoding layer of the first multi-layer neural network to the optimal reduced design parameter data, optimal design parameter data, wherein the design space comprises the optimal design parameter data. For example, design and optimization server 110 can generate a plurality of design options, each design option comprising a plurality of design parameters and can determine, based on a plurality of design constraints, an optimal design option. The design constraints can include fabrication imperfections, such as nanotubes with rounded corners. The design constraints can include structure robustness, such as oxidation of reactive material due to the exposure to the ambient. The design constraints can include characterization limitations, such as non-ideal plane wave generation with the high numerical aperture objective lenses.

At 350, the design and optimization server 110 can transmit, to the user device 140 for display, the generated optimal design parameter data. For example, design and optimization server 110 may generate a GUI and may transmit data associated with the GUI to the user device 140. As another example, user device 140 can generate a GUI and design and optimization server 110 can transmit data to user device 140 configured to be displayed by the GUI.

FIG. 3B is a flowchart of an example of a method 300B for enhanced engineering design and optimization from the perspective of the design and optimization server 110. The method 300B can be performed by the design and optimization server 110, the user device 140, the server 130, the simulation devices 120A-120n, or any combination thereof.

The design and optimization server 110 may be in communication with the user device 140, the simulation devices 120A-120n, and the server 130. Further, the design and optimization server 110 can receive response and simulation data from the server 130 and/or the simulation devices 120A-120n, train first and second neural networks to reduce the design and response spaces respectively, generate a combined neural network, determine a plurality of analytical relationships between the design space and the response space, and output data representing the determined relationships to the user device 140 for display.

At 305, the design and optimization server 110 can collect response data, which can be stored in the database 116. The response data can be response data received from a user (e.g., user device 140) and/or or response data received from the server 130. As previously mentioned, response data can include data associated with a desired response based on a set of known input parameters. For example, response data can include scattering efficiency from a cluster of nanoparticles under illumination of laser monochromatic light, absorption spectra of an array of synthesized metallo-dielectric nanospheres due to the excitation with a broadband light source, desired wavefront conversion data associated with a given photonic nanostructure, optimal fuel efficiency for a hybrid electric vehicle transmission design, in addition to many desired responses of complex, many-to-one, design and optimization problems (e.g., spiking rate of motor and visual cortex neurons under excitation of external stimuli, effect of various pathogens on the malfunctioning of malignant cells, air pollution gauging exposed to contaminating agents, global warming investigation due to emitted greenhouse gasses, and others as will be understood by one of skill in the art). The design and optimization server 110 can generate a graphical user interface (“GUI”) comprising a fillable form. The design and optimization server 110 can then transmit the GUI to the user device 140 for presentation to a user. The user device 140 can collect the desired response data via the fillable form of the GUI and transmit the desired response data to design and optimization server 110.

At 310, the design and optimization server 110 can identify, based on the desired response data, limitation data, which can be stored in the database 116. Limitation data can include data associated with the structure of a physical product to be designed. For example, limitation data may include material properties, potential nanostructure geometry, periodic/non-periodic, unit-cell structure, and fabrication limitations. The limitation data can be limitation data received from a user (e.g., user device 140) and/or or limitation data received from the server 130. The limitation data can comprise limitation data comprises structural limitation data relating to physical properties of a photonic nanostructure, such as, for example, a metasurface. Further, the design and optimization server 110 can train a neural network to determine limitation data based on desired response data.

At 315, the design and optimization server 110 can generate, based on the limitation data, simulation data comprising a design space and a response space, which can be stored in the database 116. Simulation data can include randomly generated parameters. For example, simulation data can include a design space comprising a plurality of randomly generated design parameters and a response space comprising calculated response data associated with the plurality of randomly generated design parameters. The simulation data can be simulation data received from a user (e.g., user device 140) and/or or simulation data received from the server 130. The simulation data can include training data, including a portion of the design and response spaces, and verification data, including the remainder of the design and response spaces.

At 320, the design and optimization server 110 can train, using the response space, a first multi-layer neural network to generate a reduced response space having reduced dimensionality compared to the response space, the first multi-layer neural network comprising an encoding layer, one or more hidden layers, and a decoding layer. The first multi-layer neural network can be an autoencoder that dimensionally reduces the response space to generate the reduced response space. The one or more hidden layers can range from 3 to 9. The one or more hidden layers can be 4. The autoencoder can utilize mean squared error as the cost function. The autoencoder can minimize error using the backpropagation method. The activation function for the neural network can comprise a tangent sigmoid. The activation function for the neural network can comprise one of rectified linear unit (Relu) and tangent hyperbolic. The training optimizer for the neural network can comprise one of adaptive moment estimation, stochastic gradient descent, mini-batch gradient descent, and other suitable optimizers. The learning rate for the neural network can be between 10⁻⁶ and 10⁻⁵.

At 325, the design and optimization server 110 can train, using the design space and the response space, a second neural network to generate a reduced design space having reduced dimensionality compared to the design space. The neural network can utilize mean squared error as the cost function. The neural network can minimize error using the backpropagation method. The activation function for the neural network can comprise a tangent sigmoid. The activation function for the neural network can comprise one of rectified linear unit (Relu) and tangent hyperbolic. The training optimizer for the neural network can comprise one of adaptive moment estimation, stochastic gradient descent, mini-batch gradient descent, and other suitable optimizers. The learning rate for the neural network can be between 10⁻⁶ and 10⁻⁵.

At 330, the design and optimization server 110 can generate, by cascading the second neural network with the decoding layer of the first multi-layer neural network, an optimization neural network. For example, in some implementations, the output of the first neural network can be fed into the second neural network, which turns the conventional many-to-one problem into two more manageable sub-problems, each of which can be modeled using a respective neural network (i.e., the first and second neural networks). As will be appreciated, this approach provides greater accuracy since the first neural network squeezes the space to make the input-output relation closer to one-to-one. The optimization neural network can comprise a plurality of neural networks.

At 335, the design and optimization server 110 can invert, using the design space and a response space, the optimization neural network to generate a design generation neural network. For example, in some implementations, an untrained neural network can be connected with the optimization network. The resultant neural network can then be trained using the design and response space and then detach the optimization network, resulting in the previously un trained network becoming an inverted version of the optimization network. Finally, at 366, design and optimization server 110 can output data representing determined relationships for display.

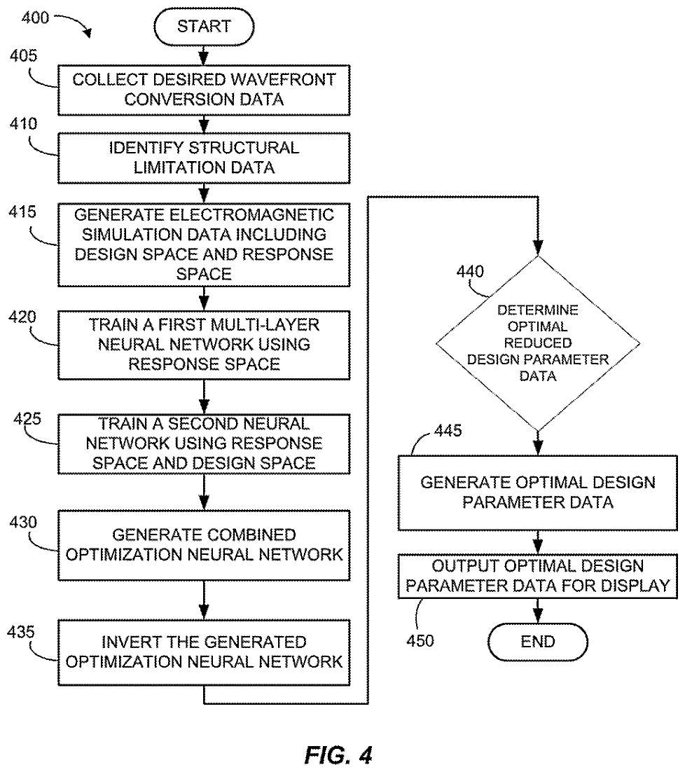

FIG. 4 is a flowchart of an example of a method 400 for enhanced engineering design and optimization from the perspective of the design and optimization server 110. The method 400 can be performed by the design and optimization server 110, the user device 140, the server 130, the simulation devices 120A-120n, or any combination thereof.

The design and optimization server 110 may be in communication with the user device 140, the simulation devices 120A-120n, and the server 130. Further, the design and optimization server 110 can receive response and simulation data from the server 130 and/or the simulation devices 120A-120n, train first and second neural networks to reduce the design and response spaces respectively, generate a combined neural network, determine a plurality of analytical relationships between the design space and the response space, and output data representing the determined relationships to the user device 140 for display.

At 405, the design and optimization server 110 can collect desired wavefront conversion data associated with a given photonic nanostructure, which can be stored in the database 116. The response data can be response data received from a user (e.g., user device 140) and/or or response data received from the server 130. The design and optimization server 110 can generate a graphical user interface (“GUI”) comprising a fillable form. The design and optimization server 110 can then transmit the GUI to the user device 140 for presentation to a user. The user device 140 can collect the desired response data via the fillable form of the GUI and transmit the desired response data to design and optimization server 110.

At 410, the design and optimization server 110 can identify, based on the wavefront conversion data, structural limitation data comprising material properties, potential nanostructure geometry, periodic/non-periodic, unit-cell structure, and fabrication limitations, which can be stored in the database 116. Structural limitation data can include data associated with the structure of a physical product to be designed. For example, structural limitation data may include material properties, potential nanostructure geometry, periodic/non-periodic, unit-cell structure, and fabrication limitations. The structural limitation data can be structural limitation data received from a user (e.g., user device 140) and/or or structural limitation data received from the server 130. The structural limitation data can comprise limitation data comprises structural limitation data relating to physical properties of a photonic nanostructure, such as, for example, a metasurface. Further, the design and optimization server 110 can train a neural network to determine structural limitation data based on desired response data.

At 415, the design and optimization server 110 can generate, based on the structural limitation data, electromagnetic simulation data comprising a design space comprising a set of design patterns and a corresponding response space comprising a corresponding set of response patterns. Electromagnetic simulation data can be stored in the database 116. Electromagnetic simulation data can include randomly generated parameters. For example, electromagnetic simulation data can include a design space comprising a plurality of randomly generated design parameters and a response space comprising calculated response data associated with the plurality of randomly generated design parameters. The electromagnetic simulation data can be electromagnetic simulation data received from a user (e.g., user device 140) and/or or electromagnetic simulation data received from the server 130. The electromagnetic simulation data can include training data, including a portion of the design and response spaces, and verification data, including the remainder of the design and response spaces.

At 420, the design and optimization server 110 can train, using the response space, a first multi-layer neural network to generate a reduced response space having reduced dimensionality compared to the response space, the first multi-layer neural network comprising an encoding layer, one or more hidden layers, and a decoding layer. The first multi-layer neural network can be an autoencoder that dimensionally reduces the response space to generate the reduced response space. The one or more hidden layers can range from 3 to 9. The one or more hidden layers can be 4. The autoencoder can utilize mean squared error as the cost function. The autoencoder can minimize error using the backpropagation method. The activation function for the neural network can comprise a tangent sigmoid. The activation function for the neural network can comprise one of rectified linear unit (Relu) and tangent hyperbolic. The training optimizer for the neural network can comprise one of adaptive moment estimation, stochastic gradient descent, mini-batch gradient descent, and other suitable optimizers. The learning rate for the neural network can be between 10⁻⁶ and 10⁻⁵.

At 425, the design and optimization server 110 can train, using the design space and the response space, a second neural network to generate a reduced design space having reduced dimensionality compared to the design space. The neural network can utilize mean squared error as the cost function. The neural network can minimize error using the backpropagation method. The activation function for the neural network can comprise a tangent sigmoid. The activation function for the neural network can comprise one of rectified linear unit (Relu) and tangent hyperbolic. The training optimizer for the neural network can comprise one of adaptive moment estimation, stochastic gradient descent, mini-batch gradient descent, and other suitable optimizers. The learning rate for the neural network can be between 10⁻⁶ and 10⁻⁵.

At 430, the design and optimization server 110 can generate, by cascading the second neural network with the decoding layer of the first multi-layer neural network, an optimization neural network. For example, in some implementations, the output of the first neural network can be fed into the second neural network, which turns the conventional many-to-one problem into two more manageable sub-problems, each of which can be modeled using a respective neural network (i.e., the first and second neural networks). As will be appreciated, this approach provides greater accuracy since the first neural network squeezes the space to make the input-output relation closer to one-to-one. The optimization neural network can comprise a plurality of neural networks.

At 435, the design and optimization server 110 can invert, using the design space and a response space, the optimization neural network to generate a design generation neural network. For example, in some implementations, an untrained neural network can be connected with the optimization network. The resultant neural network can then be trained using the design and response space and then detach the optimization network, resulting in the previously un trained network becoming an inverted version of the optimization network.

At 440, the design and optimization server 110 can determine, based on applying the design generation neural network to the desired response data, optimal reduced design parameter data, wherein the reduced design space comprises the optimal reduced design parameter data.

At 445, the design and optimization server 110 can generate, by applying the encoding layer of the first multi-layer neural network to the optimal reduced design parameter data, optimal design parameter data, wherein the design space comprises the optimal design parameter data. For example, design and optimization server 110 can generate a plurality of design options, each design option comprising a plurality of design parameters and can determine, based on a plurality of design constraints, an optimal design option. The design constraints can include fabrication imperfections, such as nanotubes with rounded corners. The design constraints can include structure robustness, such as oxidation of reactive material due to the exposure to the ambient. The design constraints can include characterization limitations, such as non-ideal plane wave generation with the high numerical aperture objective lenses.

At 450, the design and optimization server 110 can transmit, to the user device 140 for display, the generated optimal design parameter data. For example, design and optimization server 110 may generate a GUI and may transmit data associated with the GUI to the user device 140. As another example, user device 140 can generate a GUI and design and optimization server 110 can transmit data to user device 140 configured to be displayed by the GUI.

As shown in FIG. 5, some, or all, of the system 100 and methods 300 and 400 can be performed by, and/or in conjunction with, the user device 140. In some examples, the user device 140 can comprise, for example, a cell phone, a smart phone, a tablet computer, a laptop computer, a desktop computer, a sever, or other electronic device. The user device 140 may be a single server, for example, or may be configured as a distributed, or “cloud,” computer system including multiple servers or computers that interoperate to perform one or more of the processes and functionalities associated with the disclosed examples. One of skill in the art will recognize, however, that the system 100 and methods 300 and 400 can also be used with a variety of other electronic devices, such as, for example, tablet computers, laptops, desktops, and other network (e.g., cellular or internet protocol (IP) network) connected devices from which a call may be placed, a text may be sent, and/or data may be received. These devices are referred to collectively herein as the user device 140. The user device 140 can comprise a number of components to execute the above-mentioned functions and apps. As discussed below, the user device 140 comprise memory 502 including many common features such as, for example, simulator 504 and OS 510. In this case, the memory 502 can also store a design app interface 512 and an optimization app interface 514.

The user device 140 can also comprise one or more processors 516. In some implementations, the processor(s) 516 can be a central processing unit (CPU), a graphics processing unit (GPU), or both CPU and GPU, or any other sort of processing unit. The user device 140 can also include one or more of removable storage 518, non-removable storage 520, one or more transceiver(s) 522, output device(s) 524, and input device(s) 526.

In various implementations, the memory 502 can be volatile (such as random-access memory (RAM)), non-volatile (such as read only memory (ROM), flash memory, etc.), or some combination of the two. The memory 502 can include all, or part, of the functions 504, 506, 508, 512, 514, and the OS 510 for the user device 140, among other things.

The memory 502 can also include the OS 510. Of course, the OS 510 varies depending on the manufacturer of the user device 140 and currently comprises, for example, iOS 12.1.4 for Apple products, Windows 10 for Microsoft products, and Pie for Android products. The OS 510 contains the modules and software that supports a computer's basic functions, such as scheduling tasks, executing applications, and controlling peripherals.

As mentioned above, the user device 140 can also include the design app interface 512. The design app interface 512 can perform some, or all, of the functions discussed above with respect to the methods 200, 300A, 300B, and 400 for interactions occurring between the user device 140 and the design and optimization server 110. Thus, design app interface 512 can generate GUIs, receive information and display information in GUIs, work together with design and optimization server 110 to process computations in sync and parallel.

The user device 140 can also include the optimization app interface 514. The optimization app interface 514 can be associated with the many-to-one and one-to-many design problem analysis and discussed herein. For example, optimization app interface 514 can facilitate data reception and transmission between one or more servers or computing systems described herein.

The user device 140 can also include additional data storage devices (removable and/or non-removable) such as, for example, magnetic disks, optical disks, or tape. Such additional storage is illustrated in FIG. 5 by removable storage 518 and non-removable storage 520. The removable storage 518 and non-removable storage 520 can store some, or all, of the functions 504, 506, 508, 512, 514 and the OS 510.

Non-transitory computer-readable media may include volatile and nonvolatile, removable and non-removable tangible, physical media implemented in technology for storage of information, such as computer readable instructions, data structures, program modules, or other data. The memory 502, removable storage 518, and non-removable storage 520 are all examples of non-transitory computer-readable media. Non-transitory computer-readable media include, but are not limited to, RAM, ROM, electronically erasable programmable ROM (EEPROM), flash memory or other memory technology, compact disc ROM (CD-ROM), digital versatile disks (DVD) or other optical storage, magnetic cassettes, magnetic tape, magnetic disk storage or other magnetic storage devices, or any other tangible, physical medium which can be used to store the desired information and which can be accessed by the user device 140. Any such non-transitory computer-readable media may be part of the user device 140 or may be a separate database, databank, remote server, or cloud-based server.

In some implementations, the transceiver(s) 522 include any sort of transceivers known in the art. In some examples, the transceiver(s) 522 can include wireless modem(s) to facilitate wireless connectivity with the other user devices, the Internet, and/or an intranet via a cellular connection. In other examples, the transceiver(s) 522 can include wired communication components, such as a wired modem or Ethernet port, for communicating with the other user devices or the provider's Internet-based network. In this case, the transceiver(s) 522 can also enable the user device 140 to communicate with the simulation devices 120A-120n, the design and optimization server 110, and the server 130, as described herein.

In some implementations, the output device(s) 524 include any sort of output devices known in the art, such as a display (e.g., a liquid crystal or thin-film transistor (TFT) display), a touchscreen display, speakers, a vibrating mechanism, or a tactile feedback mechanism. In some examples, the output device(s) 524 can play various sounds based on, for example, whether the user device 140 is connected to a network, whether data is being sent or received, etc. Output device(s) 524 can also include ports for one or more peripheral devices, such as headphones, peripheral speakers, or a peripheral display.

In various implementations, input device(s) 526 can include any sort of input devices known in the art. The input device(s) 526 can include, for example, a camera, a microphone, a keyboard/keypad, or a touch-sensitive display. A keyboard/keypad may be a standard push button alphanumeric, multi-key keyboard (such as a conventional QWERTY keyboard), virtual controls on a touchscreen, or one or more other types of keys or buttons, and may also include a joystick, wheel, and/or designated navigation buttons, or the like.

As shown in FIG. 6, the system 100 and methods 300 and 400 can also be used in conjunction with the design and optimization server 110. The design and optimization server 110 can comprise, for example, a desktop or laptop computer, a server, bank of servers, or cloud-based server bank. Thus, while the design and optimization server 110 is depicted as single standalone servers, other configurations or existing components could be used.

In various implementations, the memory 602 can be volatile (such as random-access memory (RAM)), non-volatile (such as read only memory (ROM), flash memory, etc.), or some combination of the two. The memory 602 can include all, or part, of the functions of a design app 612 and optimization app 614, among other things. The memory 602 may also include simulator 604 and the OS 610. Of course, the OS 610 varies depending on the manufacturer of the design and optimization server 110 and the type of component. Many servers, for example, run Linux or Windows Server. The OS 610 contains the modules and software that supports a computer's basic functions, such as scheduling tasks, executing applications, and controlling peripherals.

The design and optimization server 110 can also comprise one or more processors 616, which can include a central processing unit (CPU), a graphics processing unit (GPU), or both CPU and GPU, or any other sort of processing unit. The design app 612 and optimization app 614 can provide communication between the financial institution server 110 and the user device 140 and or server 130. Thus, the design app 612 and optimization app 614 can send requests to the user device 140 that includes the prompts for user information as well as send data for output and display on user device 140.

The design and optimization server 110 can also include additional data storage devices (removable and/or non-removable) such as, for example, magnetic disks, optical disks, or tape. Such additional storage is illustrated in FIG. 6 by removable storage 618 and non-removable storage 620. The removable storage 618 and non-removable storage 620 may store some, or all, of the OS 610 and apps 612, 614.

Non-transitory computer-readable media may include volatile and nonvolatile, removable and non-removable tangible, physical media implemented in technology for storage of information, such as computer readable instructions, data structures, program modules, or other data. The memory 602, removable storage 618, and non-removable storage 620 are all examples of non-transitory computer-readable media. Non-transitory computer-readable media include, but are not limited to, RAM, ROM, EEPROM, flash memory or other memory technology, CD-ROM, DVDs or other optical storage, magnetic cassettes, magnetic tape, magnetic disk storage or other magnetic storage devices, or any other tangible, physical medium which may be used to store the desired information, and which can be accessed by the design and optimization server 110. Any such non-transitory computer-readable media may be part of the design and optimization server 110 or can be a separate database, databank, remote server, or cloud-based server.

In some implementations, the transceiver(s) 622 include any sort of transceivers known in the art. In some examples, the transceiver(s) 622 may include wireless modem(s) to facilitate wireless connectivity with the user device 140, the Internet, and/or an intranet via a cellular connection. Further, the transceiver(s) 622 can include a radio transceiver that performs the function of transmitting and receiving radio frequency communications via an antenna (e.g., Wi-Fi or Bluetooth®). In other examples, the transceiver(s) 622 can include wired communication components, such as a wired modem or Ethernet port, for communicating with the other user devices or the provider's Internet-based network. The transceiver(s) 622, can receive simulation from the simulation devices 120A-120n and/or additional data from the external server 130.

In some implementations, the output device(s) 624 include any sort of output devices known in the art, such as a display (e.g., a liquid crystal or thin-film transistor (TFT) display), a touchscreen display, speakers, a vibrating mechanism, or a tactile feedback mechanism. In some examples, the output devices may play various sounds based on, for example, whether the financial institution server 110 is connected to a network, the type of data being received (e.g., first customer data vs. second customer data), when the request is being transmitted, etc. Output device(s) 624 also include ports for one or more peripheral devices, such as headphones, peripheral speakers, or a peripheral display.

In various implementations, input device(s) 626 include any sort of input devices known in the art. For example, the input device(s) 626 can include a camera, a microphone, a keyboard/keypad, or a touch-sensitive display. A keyboard/keypad may be a standard push button alphanumeric, multi-key keyboard (such as a conventional QWERTY keyboard), virtual controls on a touchscreen, or one or more other types of keys or buttons, and may also include a joystick, wheel, and/or designated navigation buttons, or the like. **Input device that can capture device characteristics***

The specific configurations, machines, and the size and shape of various elements can be varied according to particular design specifications or constraints requiring a user device 140, design and optimization server 110, simulation devices 120A-120n, external server 130, system 100, or method 300, 400 constructed according to the principles of this disclosure. Such changes are intended to be embraced within the scope of this disclosure. The presently disclosed examples, therefore, are considered in all respects to be illustrative and not restrictive. The scope of the disclosure is indicated by the appended claims, rather than the foregoing description, and all changes that come within the meaning and range of equivalents thereof are intended to be embraced therein.

As used in this application, the terms “component,” “module,” “system,” “server,” “processor,” “memory,” and the like are intended to include one or more computer-related units, such as but not limited to hardware, firmware, a combination of hardware and software, software, or software in execution. For example, a component may be, but is not limited to being, a process running on a processor, an object, an executable, a thread of execution, a program, and/or a computer. By way of illustration, both an application running on a computing device and the computing device can be a component. One or more components can reside within a process and/or thread of execution and a component may be localized on one computer and/or distributed between two or more computers. In addition, these components can execute from various computer readable media having various data structures stored thereon. The components may communicate by way of local and/or remote processes such as in accordance with a signal having one or more data packets, such as data from one component interacting with another component in a local system, distributed system, and/or across a network such as the Internet with other systems by way of the signal.

Certain examples and implementations of the disclosed technology are described above with reference to block and flow diagrams of systems and methods and/or computer program products according to example examples or implementations of the disclosed technology. It will be understood that one or more blocks of the block diagrams and flow diagrams, and combinations of blocks in the block diagrams and flow diagrams, respectively, can be implemented by computer-executable program instructions. Likewise, some blocks of the block diagrams and flow diagrams may not necessarily need to be performed in the order presented, may be repeated, or may not necessarily need to be performed at all, according to some examples or implementations of the disclosed technology.

These computer-executable program instructions may be loaded onto a general-purpose computer, a special-purpose computer, a processor, or other programmable data processing apparatus to produce a particular machine, such that the instructions that execute on the computer, processor, or other programmable data processing apparatus create means for implementing one or more functions specified in the flow diagram block or blocks. These computer program instructions may also be stored in a computer-readable memory that can direct a computer or other programmable data processing apparatus to function in a particular manner, such that the instructions stored in the computer-readable memory produce an article of manufacture including instruction means that implement one or more functions specified in the flow diagram block or blocks.

As an example, examples or implementations of the disclosed technology may provide for a computer program product, including a computer-usable medium having a computer-readable program code or program instructions embodied therein, said computer-readable program code adapted to be executed to implement one or more functions specified in the flow diagram block or blocks. Likewise, the computer program instructions may be loaded onto a computer or other programmable data processing apparatus to cause a series of operational elements or steps to be performed on the computer or other programmable apparatus to produce a computer-implemented process such that the instructions that execute on the computer or other programmable apparatus provide elements or steps for implementing the functions specified in the flow diagram block or blocks.

Accordingly, blocks of the block diagrams and flow diagrams support combinations of means for performing the specified functions, combinations of elements or steps for performing the specified functions, and program instruction means for performing the specified functions. It will also be understood that each block of the block diagrams and flow diagrams, and combinations of blocks in the block diagrams and flow diagrams, can be implemented by special-purpose, hardware-based computer systems that perform the specified functions, elements or steps, or combinations of special-purpose hardware and computer instructions.

Certain implementations of the disclosed technology are described above with reference to user devices may include mobile computing devices. Those skilled in the art recognize that there are several categories of mobile devices, generally known as portable computing devices that can run on batteries but are not usually classified as laptops. For example, mobile devices can include, but are not limited to portable computers, tablet PCs, internet tablets, PDAs, ultra-mobile PCs (UMPCs), wearable devices, and smart phones. Additionally, implementations of the disclosed technology can be utilized with internet of things (IoT) devices, smart televisions and media devices, appliances, automobiles, toys, and voice command devices, along with peripherals that interface with these devices.

In this description, numerous specific details have been set forth. It is to be understood, however, that implementations of the disclosed technology may be practiced without these specific details. In other instances, well-known methods, structures, and techniques have not been shown in detail in order not to obscure an understanding of this description. References to “one embodiment,” “an embodiment,” “some examples,” “example embodiment,” “various examples,” “one implementation,” “an implementation,” “example implementation,” “various implementations,” “some implementations,” etc., indicate that the implementation(s) of the disclosed technology so described may include a particular feature, structure, or characteristic, but not every implementation necessarily includes the particular feature, structure, or characteristic. Further, repeated use of the phrase “in one implementation” does not necessarily refer to the same implementation, although it may.

Throughout the specification and the claims, the following terms take at least the meanings explicitly associated herein, unless the context clearly dictates otherwise. The term “connected” means that one function, feature, structure, or characteristic is directly joined to or in communication with another function, feature, structure, or characteristic. The term “coupled” means that one function, feature, structure, or characteristic is directly or indirectly joined to or in communication with another function, feature, structure, or characteristic. The term “or” is intended to mean an inclusive “or.” Further, the terms “a,” “an,” and “the” are intended to mean one or more unless specified otherwise or clear from the context to be directed to a singular form. By “comprising,” “containing,” or “including” it is meant that at least the named element, or method step is present in article or method, but does not exclude the presence of other elements or method steps, even if the other such elements or method steps have the same function as what is named.

As used herein, unless otherwise specified the use of the ordinal adjectives “first,” “second,” “third,” etc., to describe a common object, merely indicate that different instances of like objects are being referred to, and are not intended to imply that the objects so described must be in a given sequence, either temporally, spatially, in ranking, or in any other manner.

While certain examples of this disclosure have been described in connection with what is presently considered to be the most practical and various examples, it is to be understood that this disclosure is not to be limited to the disclosed examples, but on the contrary, is intended to cover various modifications and equivalent arrangements included within the scope of the appended claims. Although specific terms are employed herein, they are used in a generic and descriptive sense only and not for purposes of limitation.

This written description uses examples to disclose certain examples of the technology and also to enable any person skilled in the art to practice certain examples of this technology, including making and using any apparatuses or systems and performing any incorporated methods. The patentable scope of certain examples of the technology is defined in the claims, and may include other examples that occur to those skilled in the art. Such other examples are intended to be within the scope of the claims if they have structural elements that do not differ from the literal language of the claims, or if they include equivalent structural elements with insubstantial differences from the literal language of the claims.

### Example Use Case

The following example use case describes an example of a use of the systems and methods for enhanced engineering design and optimization described herein. It is intended solely for explanatory purposes and not to limit the disclosure in any way.

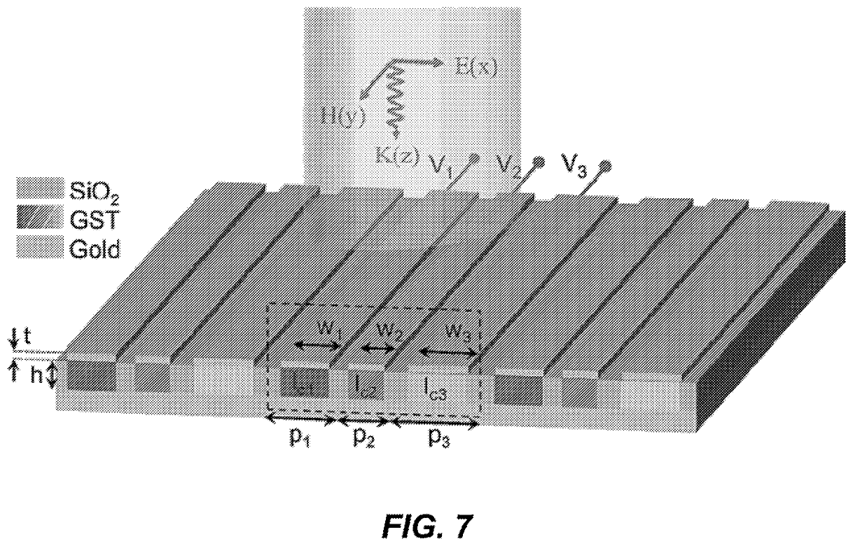

FIG. 7 depicts a metasurface (“MS”) composed of a periodic array of gold (Au) nanoribbons, having thickness t, fabricated on top of a thin layer of germanium antimony telluride (Ge₂Sb₂Te₂, depicted in FIG. 7 as GST), having height h. As further depicted, the unit cell of the structure is composed of three Au nanoribbons with different widths, w1, w2, and w3, respectively, and pitches, p1, p2, and p3, respectively. The MS has the following additional design parameter: the crystallization state of GST under the three nanoribbons, depicted as k1, k2, and k3, respectively. Additionally, the phase of GST under each nanoribbon can be changed by applying a voltage, V1, V2, and V3, respectively.

The MS depicted in FIG. 7 was illuminated with a plane wave of light with variable wavelengths in a desired wave range, specifically between 1250 and 1850 nm, in order to generate the simulation data comprising the design and response spaces. The response space of the MS was the reflectance, calculated as the far-field reflection intensity divided by the intensity of the incident field and integrated over a surface area equal to one super-cell in the far-field. In this example, the reflectance was sampled at 200 equally spaced wavelengths in the 1250-1850 nm range, resulting in a response space dimensionality of 200. In order to train the encoder, the structure was further simulated with 4000 randomly generated instances, wherein 3600 were reserved for training and 400 for validation. The training data was then used to train a series of autoencoders to study the effect of dimensional reduction from 200 to different values in the range of 1 to 20. Ultimately it was concluded that the reduced response space could be reduced to 10 and the reduced design space could be reduced to 5, resulting in a substantially less complex computational analysis.

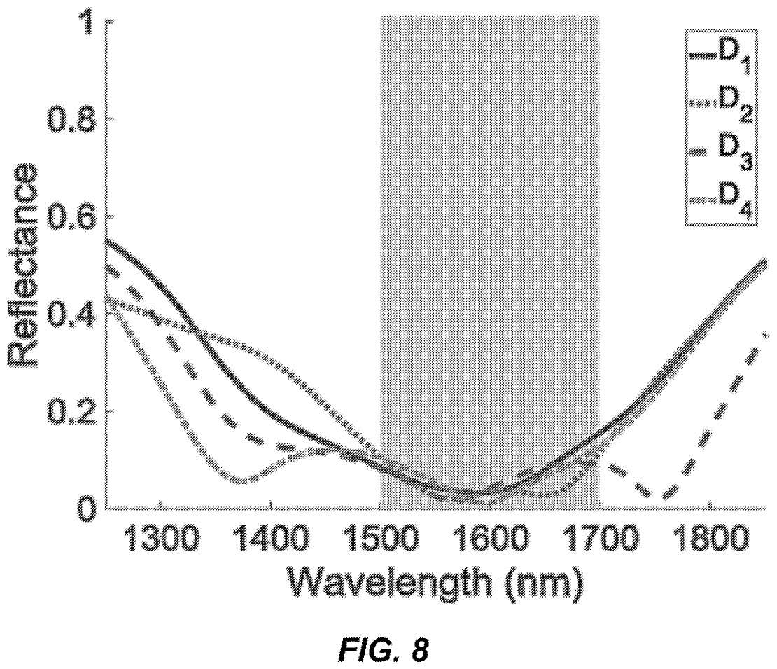

FIG. 8 depicts the responses of four different design structures generated by the neural network. The goal of the design was to have an MS that achieved maximum absorption in the 1500-1700 nm wavelength region. As shown, all the potential designs performed extremely well in the region, thus demonstrating the effectiveness of the approach utilized.

What is claimed is:

1. A system comprising:
one or more processors; and
at least one memory in communication with the one or more processors and storing instructions that, when executed by the one or more processors, are configured to cause the system to:
train, utilizing a response space, a first multi-layer neural network to generate a reduced response space having reduced dimensionality compared to the response space, the first multi-layer neural network comprising an encoding layer, one or more hidden layers, and a decoding layer;
train, utilizing a design space and the response space, a second neural network to generate a reduced design space having reduced dimensionality compared to the design space; and
generate, by cascading the second neural network with the decoding layer of the first multi-layer neural network, an optimization neural network.

2. The system of claim 1, wherein a number of the one or more hidden layers ranges from 3 to 9.

3. The system of claim 1, wherein the instructions are further configured to cause the system to:
collect desired response data;
generate simulation data comprising the design space and the response space;
invert, using the design space and the response space, the optimization neural network to generate a design generation neural network;
determine, by applying the desired response data to the design generation neural network, optimal reduced design parameter data, wherein the reduced design space comprises the optimal reduced design parameter data; and
generate, by applying the encoding layer of the first multi-layer neural network to the optimal reduced design parameter data, optimal design parameter data within the design space.

4. The system of claim 3, wherein the first multi-layer neural network is an autoencoder.

5. The system of claim 4, wherein the autoencoder utilizes mean squared error as a cost function; and
wherein the mean squared error is minimized using a backpropagation method.

6.-7. (canceled)

8. An enhanced analytical system for engineering design and optimization comprising:
one or more processors; and
memory in communication with the one or more processors and storing instructions that, when executed by the one or more processors, is configured to cause the system to:
collect desired response data;
identify, based on the desired response data, limitation data;
generate, based on the limitation data, simulation data comprising a design space and a response space;
train, utilizing the response space, a first multi-layer neural network to generate a reduced response space having reduced dimensionality compared to the response space, the first multi-layer neural network comprising an encoding layer, one or more hidden layers, and a decoding layer;
train, utilizing the design space and the response space, a second neural network to generate a reduced design space having reduced dimensionality compared to the design space;
generate, by cascading the second neural network with the decoding layer of the first multi-layer neural network, an optimization neural network;
invert, using the design space and the response space, the optimization neural network to generate a design generation neural network;
determine, by applying the desired response data to the design generation neural network, optimal reduced design parameter data, wherein the reduced design space comprises the optimal reduced design parameter data; and
generate, by applying the encoding layer of the first multi-layer neural network to the optimal reduced design parameter data, optimal design parameter data within the design space by:
generating design options, each design option comprising design parameters; and
determining, based on design constraints, an optimal design option from among the design options.

9. The enhanced analytical system of claim 8, wherein the design constraints are selected from the group consisting of fabrication imperfections, structure robustness, characterization limitations, and combinations thereof.

10. The enhanced analytical system of claim 8, wherein the limitation data comprises structural limitation data relating to physical properties of a photonic nanostructure.

11. (canceled)

12. The system of claim 1, wherein the instructions are further configured to cause the system to:
collect desired response data;
identify, based on the desired response data, limitation data;
generate, based on the limitation data, simulation data comprising the design space and the response space; and
utilize the optimization neural network to determine analytical relationships between the design space and the response space.

13. The system of claim 12, wherein the design space comprises randomly generated design parameters; and
wherein the response space comprises calculated response data associated with the randomly generated design parameters.

14. The system of claim 13, wherein each of the randomly generated design parameters comprise physical parameters associated with a photonic nanostructure; and
wherein the associated calculated response data comprises a calculated characteristic of the photonic nanostructure.

15. The system of claim 14, wherein the photonic nanostructure comprises a metasurface.

16. The system of claim 12, wherein an activation function for each neural network comprises a tangent sigmoid.

17. The system of claim 1, wherein the instructions are further configured to cause the system to:
collect desired wavefront conversion data;
identify, based on the desired wavefront conversion data, structural limitation data comprising material properties, potential nanostructure geometry, periodic/non-periodic, unit-cell structure, and fabrication limitations;
generate, based on the structural limitation data, electromagnetic simulation data comprising a design space, the design space comprising a set of design patterns and the response space comprising a corresponding set of response patterns;
invert, using the design space and the response space, the optimization neural network to generate a design generation neural network;
determine, based on applying the design generation neural network to the desired wavefront conversion data, optimal reduced design parameter data, wherein the reduced design space comprises the optimal reduced design parameter data; and
generate, by applying the encoding layer of the first multi-layer neural network to the optimal reduced design parameter data, optimal design parameter data, wherein the design space comprises the optimal design parameter data.

18. The system of claim 17, wherein the response space and the reduced response space have a one to one dimensional relationship.

19. The system of claim 17, wherein the reduced design space and the reduced response space have a one to one dimensional relationship.

20. The system of claim 17, wherein a training optimizer for each neural network comprises adaptive moment estimation.

21. The enhanced analytical system of claim 8, wherein a number of the one or more hidden layers is 4.

22. The enhanced analytical system of claim 8, wherein the first multi-layer neural network is an autoencoder that utilizes mean squared error as a cost function; and
wherein the mean squared error is minimized using a backpropagation method.

23. A method comprising:
training, utilizing a response space, a first multi-layer neural network to generate a reduced response space having reduced dimensionality compared to the response space, the first multi-layer neural network comprising an encoding layer, one or more hidden layers, and a decoding layer;
training, utilizing a design space and the response space, a second neural network to generate a reduced design space having reduced dimensionality compared to the design space; and
generating, by cascading the second neural network with the decoding layer of the first multi-layer neural network, an optimization neural network.

24. The method of claim 23 further comprising:
collecting desired response data;
identifying, based on the desired response data, limitation data; and
generating, based on the limitation data, simulation data comprising the design space and the response space.

25. The method of claim 24 further comprising:
inverting, using the design space and the response space, the optimization neural network to generate a design generation neural network;
determining, by applying the desired response data to the design generation neural network, optimal reduced design parameter data, wherein the reduced design space comprises the optimal reduced design parameter data; and
generating, by applying the encoding layer of the first multi-layer neural network to the optimal reduced design parameter data, optimal design parameter data within the design space.

26. The method of claim 25 further comprising-utilizing the optimization neural network to determine analytical relationships between the design space and the response space.

27. The method of claim 23 further comprising:
collecting desired wavefront conversion data;
identifying, based on the desired wavefront conversion data, structural limitation data comprising material properties, potential nanostructure geometry, periodic/non-periodic, unit-cell structure, and fabrication limitations;
generating, based on the structural limitation data, electromagnetic simulation data comprising a design space, the design space comprising a set of design patterns and the response space comprising a corresponding set of response patterns;
inverting, using the design space and the response space, the optimization neural network to generate a design generation neural network;
determining, based on applying the design generation neural network to the desired wavefront conversion data, optimal reduced design parameter data, wherein the reduced design space comprises the optimal reduced design parameter data; and
generating, by applying the encoding layer of the first multi-layer neural network to the optimal reduced design parameter data, optimal design parameter data, wherein the design space comprises the optimal design parameter data.
